(19) United States
(12) Patent Application Publication
(10) Pub. No.: US 2007/0163502 A1
(43) Pub. Date: Jul. 19, 2007

(54) Substrate processing apparatus

(76) Inventors: Toshihisa Nozawa, Hyogo-Ken (JP); Osamu Morita, Hyogo-Ken (JP); Tamaki Yuasa, Hyogo-Ken (JP); Koji Kotani, Hyogo-Ken (JP)

Correspondence Address: SMITH, GAMBRELL & RUSSELL, 1850 M STREET, N.W., SUITE 800, WASHINGTON, DC, 20036, US

(21) Appl. No.: 10/585,408

(22) PCT Filed: Dec. 24, 2004
(86) PCT No.: PCT/JP04/19418

§ 371 Date: Jul. 7, 2006

(30) Foreign Application Priority Data
Jan. 9, 2004 (JP) 2004-004483

(51) Int. Cl. C23C 16/00; C23C 14/00; B05C 11/00

(52) U.S. Cl. 118/723 R; 118/50; 118/666

(57) ABSTRACT

In a substrate processing apparatus for processing a substrate for manufacturing a semiconductor device, a mist passage (5) is formed to pass through a part of a processing vessel (2) as an object to be cooled. There are disposed a mist generator (64) that generates a mist, and a gas supply source (62) that supplies a carrier gas for carrying the generated mist. A temperature of the part to be cooled is detected by a temperature sensor (49). When the detected temperature exceeds a predetermined temperature, a water mist, for example, is allowed to flow into the mist passage so as to cool the processing vessel by a heat of evaporation of the mist. Thus, the temperature of the processing vessel can be promptly lowered, and thus a plasma process can be performed under an atmosphere of a stable temperature.

### FIELD OF THE INVENTION

The present invention relates to a substrate processing apparatus having an object to be cooled, for processing a substrate for manufacturing a semiconductor device, with the use of a plasma, heat, and so on.

### BACKGROUND ART

Various kinds of substrate processing apparatuses are used. For example, there are a plasma processing apparatus that performs a film deposition process and an etching process to a substrate, such as a semiconductor wafer, with the use of a plasma, and a heat processing apparatus that performs an annealing process and an oxidation process in a heating furnace. Some of these apparatuses may have an object to be cooled whose temperature should be prevented from increasing. In the plasma-processing apparatus, for example, when a process gas is excited by an energy such as a microwave to generate a plasma, a temperature of the apparatus is raised by the heat from the plasma.

On the other hand, since processes such as the etching process and the film deposition process are sensitive to temperatures of a substrate and a processing vessel, it is required to maintain these temperatures to be appropriate ones as much as possible. A heater is generally used as temperature adjusting means. However, in the case of the plasma processing apparatus, when the temperature is controlled only by a heater, the temperature is undesirably elevated, because it is impossible to remove a heat upon generation of a plasma. Thus, the apparatus needs to be cooled, when a heat is generated by a plasma.

For example, JP2002-299330A describes a plasma processing apparatus having a cooling function. A structure thereof is schematically shown in FIG. 10. In the apparatus, a table 12 for arranging thereon a semiconductor wafer W is disposed in a processing vessel 11 made of, e.g., aluminum. A microwave is supplied to a planar antenna 14 through a waveguide 13 disposed on an upper part of the processing vessel 11. The microwave is irradiated into the processing vessel 11 from the planar antenna 14 through a transmission window 15, so that a process gas in the processing vessel 11 is ionized to form a plasma. A cooling passage 16 is disposed on the upper part of the processing vessel 11 to cool the apparatus when a plasma is generated. By combining a heating operation by a heater, not shown, and a cooling operation by a coolant flowing through the cooling passage 16, a temperature is controlled such that the upper part of the apparatus is maintained at a set temperature. A cooling water is used as a coolant that circulates in the coolant passage 16.

However, to circulate a coolant requires a chiller unit. Such a chiller unit is of a large size including a freezing machine, a passage for a primary cooling water, a temperature-adjusting tank, a heater, and so on. Thus, the chiller unit requires an increased installation cost and a large occupation area. Further, the chiller unit is disadvantageous in that it consumes a measurable amount of power.

Generally, when a cooling water is used as a coolant in a substrate processing apparatus, not limited to the plasma processing apparatus, an applicable scope of the cooling water is small because its upper limit temperature is not more than 80° C. When Galden (registered trademark of Ausimont Inc.) is used as a coolant, a temperature thereof can be raised up to about, e.g., 150° C. However, a circulation of a coolant at a high temperature in a factory poses a problem in terms of safety. In addition, the Galden is disadvantageous in that it takes a long time before the Galden becomes a steady state, because of its significantly high viscosity. Alternatively, a gas such as air may be used as a coolant. In this case, although a supply system can be simplified, a gas lacks in cooing ability.

### DISCLOSURE OF THE INVENTION

The present invention has been made in view of the above circumstances. The object of the present invention is to provide a substrate processing apparatus having a simple structure but an excellent cooling ability, the apparatus being capable of cooling an object to be cooled while saving energy.

In order to achieve this object, the present invention provides a substrate processing apparatus for processing a substrate for manufacturing a semiconductor device, comprising an object to be cooled, the apparatus further comprising:

a mist generator that generates a mist;

a carrier-gas supply source that supplies a carrier gas for carrying the mist generated in the mist generator; and

a mist passage through which the mist carried by the carrier gas flows to cool the object.

In the substrate processing apparatus, by allowing the mist to flow through the mist passage, a heat of the object can be drawn from same by a heat of evaporation of the mist. Thus, the object can be rapidly cooled. The use of the mist as a coolant eliminates the use of a chiller unit that is needed when a cooling water is used as a coolant. Thus, a structure of the overall apparatus can be simplified, and an occupation area thereof can be reduced. In addition, the apparatus is advantageous in terms of cost in that the apparatus can save energy because of its low power consumption. Moreover, since the object is cooled by a heat of evaporation of the mist, it is not necessary to circulate a coolant of a high temperature in a factory, which is advantageous in terms of safety.

For example, the object is at least a part of a processing vessel in which a substrate received therein is processed.

For example, the substrate is processed in the processing vessel with the use of a plasma.

In this case, when the temperature of the processing vessel is increased by a plasma generation, the object can be promptly cooled to a predetermined temperature, and thus a plasma process can be stably carried out.

Preferably, the substrate processing apparatus further comprises a heater that heats the object, at least when no plasma is generated.

The substrate processing apparatus may further comprise a heating furnace that receives the processing vessel, wherein the mist passage is formed as a space defined between the processing vessel and the furnace.

In this case, the object to be cooled may be a part other than the processing vessel, e.g., an outer peripheral part of the heating furnace.

Preferably, the substrate processing apparatus further comprises:

a temperature sensor that detects a temperature of the object; and

a controller that controls the mist generator and the gas supply source, based on a temperature detected by the temperature sensor.

The controller may carry out a control operation to stop a generation of the mist by the mist generator and a supply of the carrier gas from the gas supply source, when the detected temperature of the temperature sensor is not more than a reference value.

Alternatively, the controller may carry out a control operation to stop a generation of the mist by the mist generator, while continuing a supply of the carrier gas from the gas supply source, when the detected temperature of the temperature sensor is not more than a reference value.

Preferably, the controller controls at least one of a flow rate of the mist and a flow rate of the carrier gas in the mist passage.

Preferably, the substrate processing apparatus further comprises a gas-liquid separator that separates the mist circulated in the mist passage from the carrier gas, and collects the separated mist as a liquid, wherein the mist generator generates the mist from the liquid collected by the separator.

### BRIEF DESCRIPTION OF THE DRAWINGS

FIG. 1 is a longitudinal sectional view of a plasma processing apparatus in one embodiment of a substrate processing apparatus according to the present invention;

FIG. 2 is a block diagram showing details of a mist supply part in the plasma processing apparatus shown in FIG. 1;

FIG. 3 is a view showing more concretely a mist generator show in FIG. 2;

FIG. 4 is a view showing more concretely a gas-liquid separator shown in FIG. 2;

FIG. 5 is a time chart showing an operation of the plasma processing apparatus shown in FIG. 1;

FIG. 6 is a view showing similarly to FIG. 2 another embodiment of the substrate processing apparatus according to the present invention;

FIG. 7 is a longitudinal sectional view of a vertical heat processing apparatus in yet another embodiment of a substrate processing apparatus according to the present invention;

FIG. 8 is a graph showing experiment results of Examples 1 and 2 and Comparative Examples 1 and 2;

FIG. 9 is a diagram comparing (a) a graph showing an experiment result of Example 3 and (b) a graph showing an experiment result of Comparative Example 3; and

FIG. 10 is a longitudinal sectional view of a plasma processing apparatus as a conventional substrate processing apparatus.

### BEST MODE FOR CARRYING OUT THE INVENTION

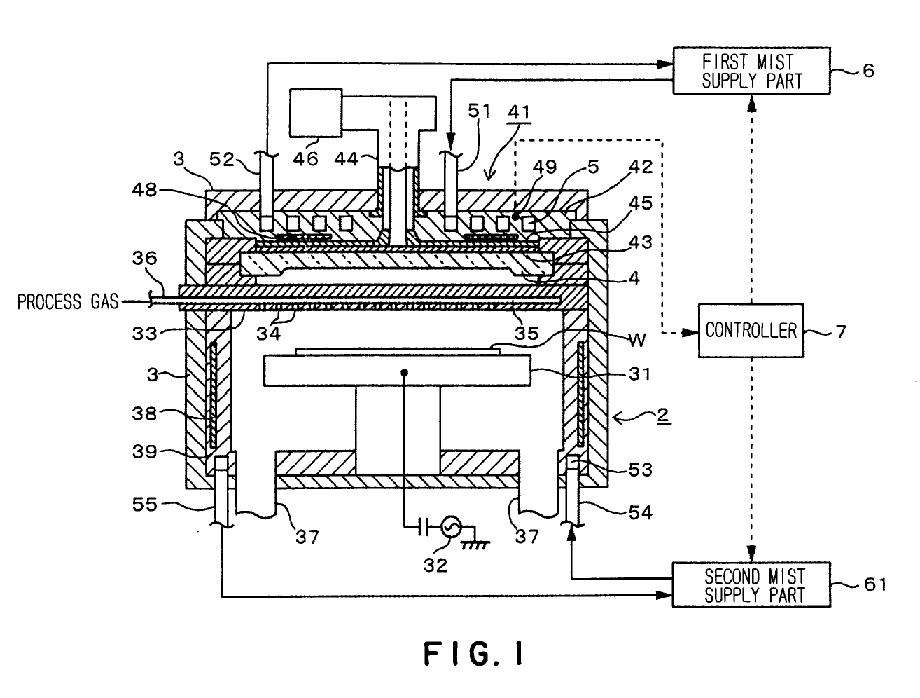

Embodiments of the present invention will be described in detail below with reference to the accompanied drawings. FIG. 1 is a view generally showing a plasma processing apparatus in one embodiment of a substrate processing apparatus according to the present invention. In FIG. 1, the reference number 2 depicts a processing vessel. The processing vessel 2 includes: a vessel body 39 made of aluminum; a heat-insulating member 3 surrounding a circumference of the vessel body 39; an antenna body 42 disposed on an upper part of the vessel body 39; and so on. The vessel body 39 defines a vacuum processing space. A table 31 on which a semiconductor wafer (hereinafter referred to as “wafer”) W is arranged is disposed in the processing vessel 2. A high-frequency bias power 32 of, e.g., 13.65 MHz is connected to the table 31.

A gas supply member 33 made of, e.g., a disk-shaped electric conductor is disposed above the table 31. The gas supply member 33 has a plurality of gas supply holes 34 formed in a surface thereof facing the table 31. Gas passages 35 in the form of a lattice are formed in the gas supply member 33 to communicate with the gas supply holes 34. A gas supply channel 36 is connected to the gas passages 35. A process gas source, not shown, is connected to the gas supply channel 36. A process gas required for a plasma process is supplied from the process gas source into the processing vessel 2 through the gas supply channel 36, the gas passages 35, and the gas supply holes 34.

The gas supply member 33 has a plurality of openings, not shown, that pass through the gas supply member 33. These openings are formed for allowing a plasma to pass therethrough into the space below the gas supply member 33. The openings are formed in parts between the gas passages 35 adjacent to each other, for example. An evacuation pipe 37 is connected to a bottom part of the processing vessel 2. Not-shown vacuum evacuation means is connected to a proximal end side of the evacuation pipe 37.

A dielectric plate (microwave transmission window) 4 made of, e.g., quartz is disposed above the gas supply member 33. An antenna 41 is disposed on the plate 4 such that the antenna 41 and the plate 4 are in tight contact with each other. Not limited to quartz, a material of the dielectric plate 4 may be alumina, for example. The antenna 41 is provided with an antenna body 42, and a planar antenna member (slot plate) 43 disposed below the antenna body 42. A plurality of slots are circumferentially formed in the planar antenna member 43. The antenna body 42 and the planar antenna member 43, that are made of conductors, have substantially disk-like shapes, and are connected to a coaxial waveguide 44. A wave retardation plate 45 is disposed between the antenna body 42 and the planar antenna member 43. The antenna body 42, the planar antenna member 43, and the wave retardation plate 45 constitute a radial line slot antenna (RLSA).

The antenna 41 as constituted above is mounted on the processing vessel 2 through a sealing member, not shown, such that the planar antenna member 43 is in tight contact with the dielectric plate 4. The antenna 41 is connected to a microwave generator 46 disposed outside the apparatus through the coaxial waveguide 44. Thus, a microwave of a frequency of, e.g., 2.45 GHz or 8.4 GHz is supplied into the apparatus.

The antenna body 42 has a first mist passage 5 that circumferentially, spirally passes therethrough. An inlet channel 51 formed of a pipeline, for example, is connected to one end of the first mist passage 5. An outlet channel 52 formed of a pipeline, for example, is connected to the other end of the first mist passage 5. The first mist passage 5, the inlet channel 51, and the outlet channel 52 form a circulation channel. A first mist supply part 6, which is described below, is arranged on the circulation channel.

The antenna body 42 is provided with a heater 48, and a temperature sensor 49 that detects a temperature in the processing vessel 2. A temperature detected by the temperature sensor 49 is sent to the controller 7.

A second mist passage 53 is formed in a lower part of the processing vessel 2 to circumferentially pass through a wall surface thereof. An inlet channel 54 and an outlet channel 55 are connected to the second mist passage 53 so as to form a circulation channel. A second mist supply part 61 identical to the first mist supply part 6 is arranged on the circulation channel.

As described below, the first mist supply part 6 and the second mist supply part 61 are respectively controlled by the controller 7.

Herebelow, the first mist supply part 6 and the controller 7 are described in detail.

The first mist supply part 6 includes a mist generator 64 that generates a mist, and a gas supply source 62 that supplies a carrier gas (e.g., air) for carrying the mist generated by the mist generator 64.

The gas supply source 62 is connected to the mist generator 64, which is disposed on an upstream end of the inlet channel 51, through a flow-rate adjustor 63 that adjusts a flow rate of the carrier gas. A gas-liquid separator 65 is disposed on a downstream end of the outlet channel 52. The gas-liquid separator 65 separates the carrier gas containing the mist into the carrier gas and the mist. The mist separated by the gas-liquid separator 65 is stored in a collected liquid tank 66. Then, the collected liquid is sent to the mist generator 64, and is used again as a material liquid for the mist.

The controller 7 is connected to the gas supply source 62, the flow-rate adjustor 63, and the mist generator 64 so as to control these members. The gas supply source 62 has an air cylinder and a valve, for example. Under the control of an opening/closing operation of the valve by the controller 7, a supply of the carrier gas is conducted and stopped.

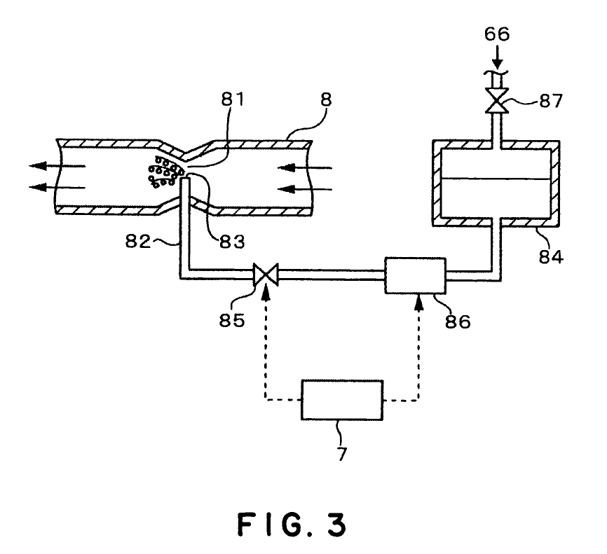

FIG. 3 is a view showing the mist generator 64 more concretely. In FIG. 3, the reference number 8 depicts a pipe through which the carrier gas supplied from the gas supply source 62 flows. The pipe 8 has a reduced-diameter part 81. Near a center of the reduced-diameter part 81, there is positioned an opening 83 of a mist liquid supply pipe 82 that passes through the pipe 8. The mist liquid supply pipe 82 is connected to a mist liquid tank 84 storing therein a liquid as a material of the mist (e.g., water, alcohol water (diluted alcohol), and ammonia). The mist liquid supply pipe 82 is provided with a valve 85 and a current meter 86 that are controlled by the controller 7.

At the reduced-diameter part 81 of the pipe 8, a current velocity of the gas is increased so that a pressure (P1) is decreased. The pressure (P1) is lower than a pressure (P0) in the mist liquid tank 84. Because of this pressure difference (P0-P1), the liquid is pumped out of the opening 83, which is positioned near the center of the reduced-diameter part 81, of the mist liquid supply pipe 82. The pumped liquid is diffused by the carrier gas flowing through the pipe 8 to become a mist (nebulized liquid). The pressure difference (P0-P1) is determined by a flow rate of the carrier gas supplied from the gas supply source 62. That is, a flow rate of the mist can be adjusted by adjusting a flow rate of the carrier gas by means of the flow-rate adjustor 63.

Alternatively, a flow rate of the mist may be adjusted by the controller 7 that controls the valve 85 to adjust an amount of the liquid blown out from the opening 83, while monitoring the detected value of the current meter 86. In order to stop a generation of the mist, the valve 85 is closed.

The mist liquid tank 84 is connected to the collected liquid tank 66 through a pipeline on which a valve 87 is arranged. When the valve 87 is opened, the liquid stored in the collected liquid tank 66 is supplied into the mist liquid tank 84.

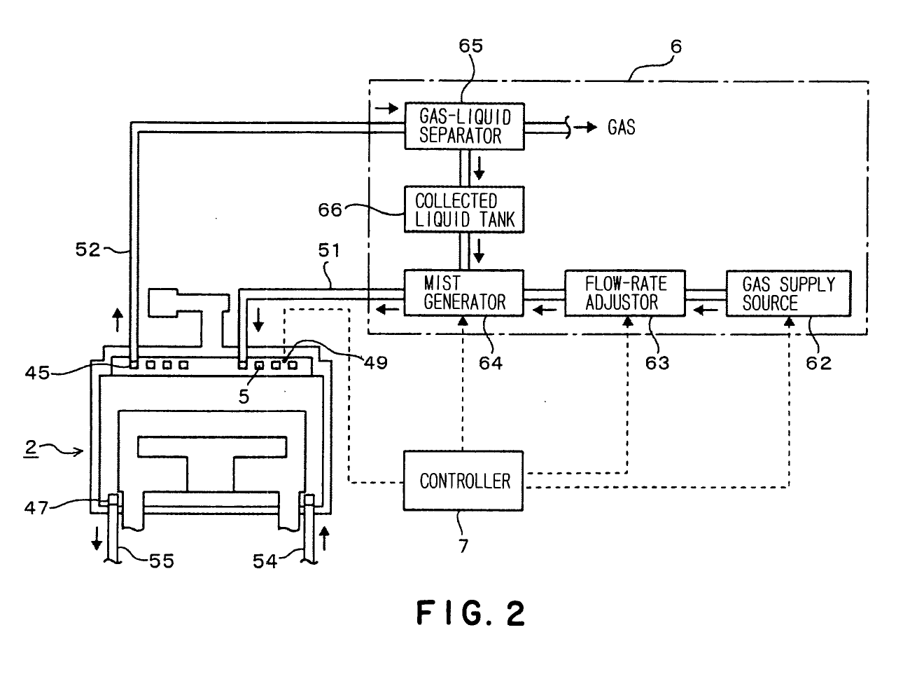

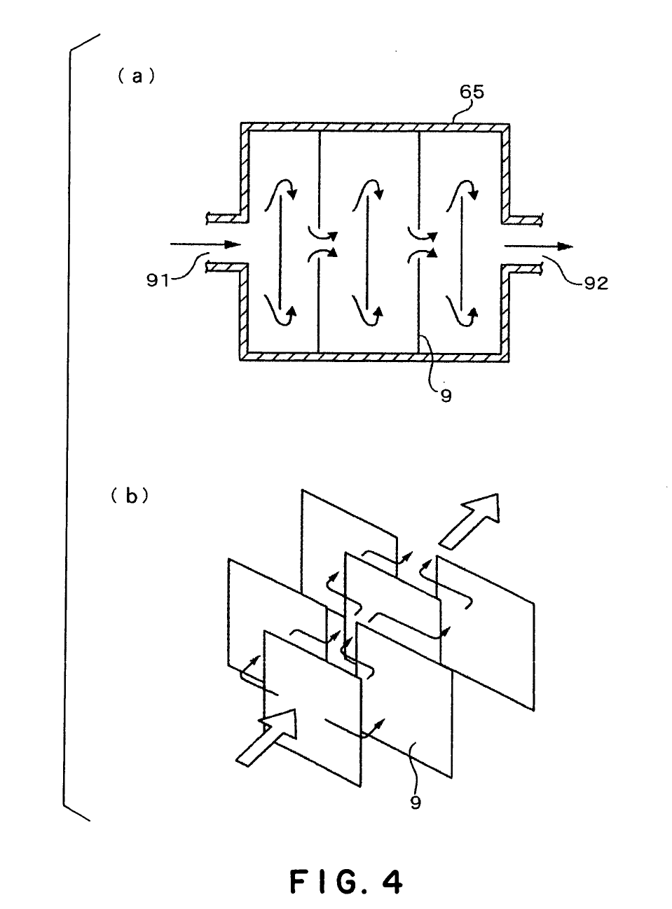

FIG. 4(a) is a horizontal sectional view of the gas-liquid separator 65. As shown in a perspective view of FIG. 4(b), a plurality of fins 9 are arranged inside the gas-liquid separator 65, such that a meandering passage is formed. The gas-liquid separator 65 has an inlet port 91 and outlet port 92. An outlet port, not shown, for discharging the separated liquid is formed in a lower surface of the gas-liquid separator 65. Due to this structure, when the gas containing the mist hits the fins 9, only the mist adheres to the fins 9, and the gas from which the mist is separated is discharged through the outlet port 92. When an amount of the mist adhering to the fins 9 is increased, the mist becomes large liquid droplets to drop from the fins 9 by the gravity. The dropped liquid is discharged from the outlet port, and is collected in the collected liquid tank 66 (FIG. 2).

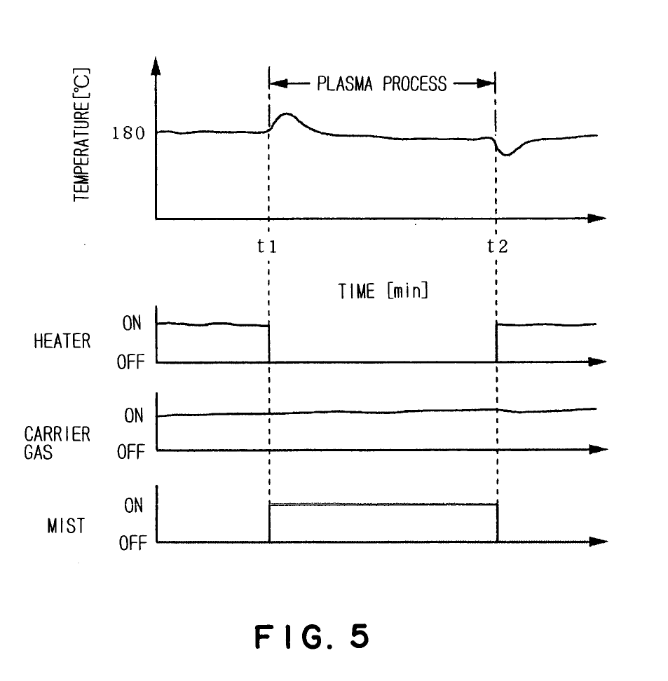

Next, an operation of the plasma processing apparatus having the above-described structure is described with reference to FIG. 5.

Upon startup of the plasma processing apparatus, the heater 48 is turned on, so that a temperature in the upper part of the processing vessel 2 is raised and maintained at a set temperature. In more detail, a power supply to the heater 48 is controlled such that a temperature detected by the temperature sensor 49 coincides with the set temperature. A value of the set temperature is, e.g., 180° C., which is identical to a value of an adequate temperature in a processing space that is suitable for performing a plasma process, such as a plasma etching process, to the wafer W.

Following thereto, the wafer W is loaded into the processing vessel 2 from outside, and is arranged on a surface of the table 31. Thereafter, process gases, i.e., an inert gas such as Ar gas, and an etching gas such as a halogen compound gas, are supplied into the processing vessel 2. At the same time, a microwave is irradiated into the processing vessel 2 from the microwave generator 46 through the antenna member 43 and the dielectric plate 4, so that the process gases are ionized to form a plasma. At this time, a bias power is applied to the table 31 from the bias power 32, and a film formed on a surface of the wafer W is etched by the plasma.

Now, taking account of a temperature detected by the temperature sensor 49 in the upper part of the processing vessel 2 that is an object to be cooled, the temperature changes as shown in FIG. 5. Note that a supply of the carrier gas from the gas supply source 62 is conducted without interruption.

Suppose that a plasma is generated at a timing t1. Before the timing t1, the heater 48 is kept ON, and the detected temperature of the temperature sensor 49 is constantly retained at about 180° C.

A plasma generated at the timing t1 increases the detected temperature of the temperature sensor 49. Thus, the heater 48 is turned off, and the mist is supplied into the first mist passage 5. Specifically, a predetermined amount of the mist is generated by opening the valve 85 of the mist generator 64. The mist is carried by the carrier gas to flow through the inlet channel 51, and is then circulated in the first mist passage 5. The mist circulated in the mist passage 5 is evaporated by a heat generated in the processing vessel 2 to draw the heat as a heat of evaporation. As a result, it is possible to cool the processing vessel 2 (herein, an upper surface part of the processing vessel 2 as an object to be cooled) whose temperature is just to be elevated by the generation of the plasma. Thus, the detected temperature of the temperature sensor 49 can be lowered to around the set temperature.

Thereafter, the detected temperature of the temperature sensor 49 tends to be stabilized around the set temperature, by a balance of an exotherm and an endotherm.

Afterward, when the generation of the plasma is stopped at a timing t2, the temperature of the processing vessel 2 is lowered. Thus, the heater is again turned on, while a supply of the mist is stopped, so as to maintain the detected temperature of the temperature sensor 49 around the set temperature.

In the above embodiment, the upper part of the processing vessel 2 as an object to be cooled is cooled by circulating the mist in the mist passage 5. Since the object is cooled by drawing the heat, which is generated by the generation of the plasma, as a heat of evaporation of the mist, the object can be rapidly cooled. As a result, when the temperature of the processing vessel 2 in the plasma processing apparatus is increased by the generation of a plasma, the temperature can be promptly decreased to a predetermined one. Therefore, a plasma process, such as an etching process, can be stably performed to a substrate.

The use of the mist as a coolant eliminates the use of a chiller unit that is needed when a cooling water is used as a coolant. Thus, a structure of the overall apparatus can be simplified, and an occupation area thereof can be reduced. In addition, the apparatus is advantageous in terms of cost in that the apparatus can save energy because of its low power consumption. Moreover, since the object to be cooled is cooled by a heat of evaporation of the mist, it is not necessary to circulate a coolant of a high temperature in a factory, which is advantageous in terms of safety.

Besides, the mist that has been circulated in the mist passage 5 is collected by the gas-liquid separator 65, and the collected mist is reused. That is, resources can be effectively utilized, which leads to a cost reduction.

The present invention is not limited to the above embodiment in which a supply of the mist is conducted/stopped depending on whether the detected value of the temperature sensor 49 exceeds a reference value (about 180° C. in the above embodiment) or not, while a supply of the carrier gas from the gas supply source is continued. That is, when the detected value is equal to or less than the reference value, a supply of the carrier gas, as well as a supply of the mist, may be stopped. When the detected value exceeds the reference value, both the carrier gas and the mist may be supplied.

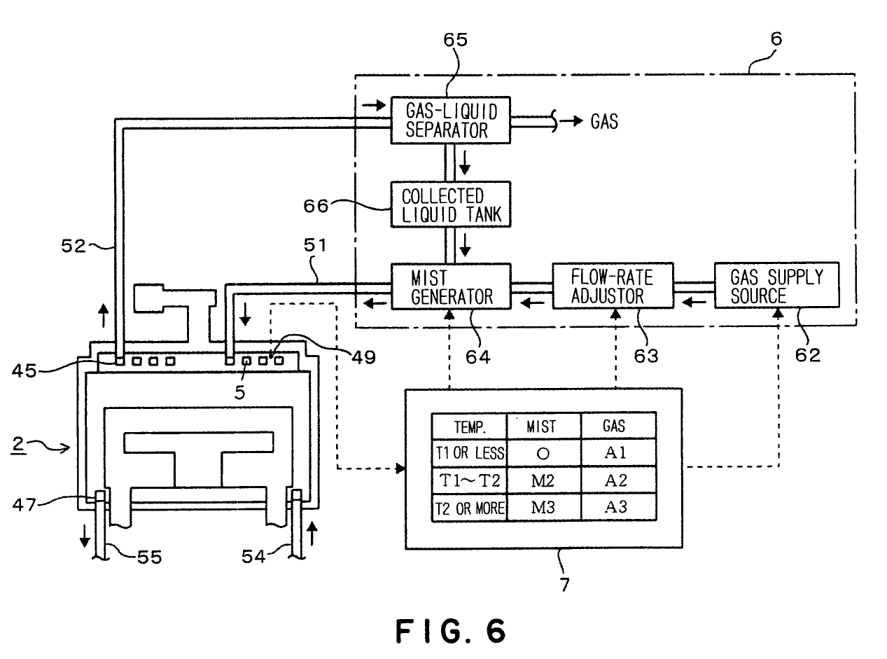

Alternatively, at least one of a supply amount of the mist and a supply amount of the carrier gas may be varied depending on the detected value of the temperature sensor 49. FIG. 6 shows such a modification.

As shown in FIG. 6, the controller 7 is provided with a memory that stores a data map, in which correlations of temperature zones, flow rates of the mist, and flow rates of the carrier gas are written. The controller 7 checks the detected temperature against the data map so as to calculate a flow rate of the mist and a flow rate of the carrier gas. A temperature T1 in the map shown in FIG. 6 is, for example, a temperature of the processing vessel 2 heated by the heater 48 when no plasma is generated (temperature suitable for a plasma process). When the detected temperature is not more than the temperature T1, a flow rate of the mist is zero, while a flow rate of the carrier gas is A1. When the detected temperature is between the temperatures T1 and T2, a flow rate of the mist is M2, while a flow rate of the carrier gas is A2. When the detected temperature is equal to or higher than the temperature T2, a flow rate of the mist is M3, while a flow rate of the carrier gas is A3. The relationships of these flow rates are M2<M3, and A1<A2<A3.

In this modification, although the number of the temperature zones is three, and different flow rates are assigned to the respective zones, the number of the temperature zones may be four or more. In this manner, the flow rates of the mist and the carrier gas are designed to be increased, in proportion to an elevation in the detected temperature, by setting a plurality of temperature zones. This enables a more delicate temperature control. Simultaneously, the temperature can be more promptly lowered to a predetermined one.

Not limited to the plasma processing apparatus, the substrate processing apparatus according to the present invention can be applied to a heat processing apparatus described below.

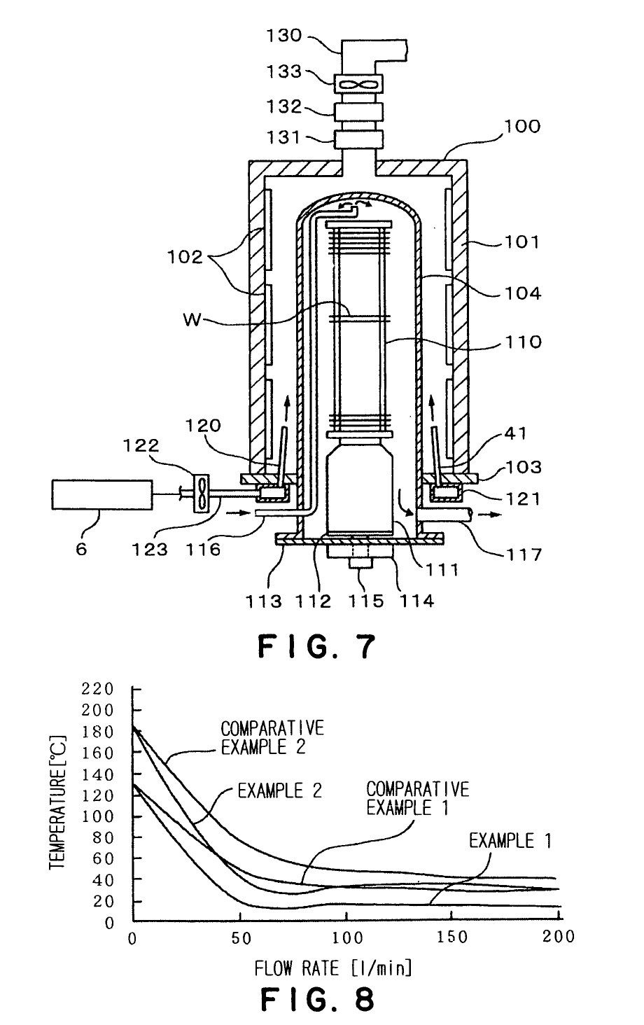

FIG. 7 shows such a vertical heat processing apparatus. As shown in FIG. 7, the heat processing apparatus is equipped with a vertical heating furnace 100 receiving a reaction tube 104 serving as a processing vessel. The heating furnace 100 includes a substantially cylindrical heat-insulating wall 101, and a heater 102 made of, e.g., a heating resistor, that is circumferentially arranged along an inside surface of the heat-insulating wall 101. A lower end part of the heat-insulating wall 101 is secured on a base body 103.

The reaction tube 104 received in the heating furnace 100 is made of, e.g., quartz, and defines therein a heat processing space. A lower part of the reaction tube 104 is secured on the base body 103. A mist passage in this heat processing apparatus is formed as a space that is defined between the heating furnace 100 and the reaction tube 104. In order to supply a cooling gas containing a mist into the space serving as the mist passage, the base body 103 has a plurality of nozzles 120 that are arranged in a circumferential direction. These nozzles 120 are connected to a ring-shaped blast header 121 disposed on a bottom of the base body 103. The gas containing the mist is supplied into the blast header 121 from a blast pipe 123 on which a blast fan 122 is arranged. The blast pipe 123 is connected to a mist supply part 6 similar to that of FIG. 2. An evacuation pipe 130 for evacuating the cooling gas containing the mist is connected to a ceiling of the heating furnace 100. The evacuation pipe 130 is provided with an opening/closing shutter 131, a cooling mechanism 132, and an evacuation fan 133, in this order from below.

The reaction tube 104 includes therein a wafer boat 110 that holds a plurality of vertically arranged substrates, such as wafers W, with spaces therebetween. A lower end part of the wafer boat 110 is fixed on a lid body 113 through a heat-insulating member 111 and a turntable 112. A function of the lid body 113 is to open and close a lower opening of the reaction tube 104. A boat elevator 114 is connected to the lid body 113. A rotating mechanism 115 is connected to the boat elevator 114, so that the wafer boat 110 together with the turntable 112 is rotated. The wafer boat 110 is loaded into the reaction tube 104 and is unloaded therefrom, by a vertical movement of the boat elevator 114.

A gas supply pipe 116 passes horizontally through a lower part of the reaction tube 104. The gas supply pipe 116 vertically stands up inside the reaction tube 104. A distal end of the gas supply pipe 116 is bent so as to blow a process gas toward a center of the ceiling of the reaction tube 104. The process gas supplied into the reaction tube 104 from the gas supply line 116 is evacuated by a vacuum pump, not shown, from an evacuation channel 117 disposed on the lower part of the reaction tube 104.

In the heat processing apparatus, an atmosphere in the reaction tube 104 is heated to a predetermined temperature, and the wafer W is subjected to heat processes such as a film deposition process, an oxidation process, and an annealing process. After these processes are completed, the gas containing the mist that has been supplied from the mist supply part 6 is circulated in the mist passage defined between the heat-insulating member 101 and the reaction tube 104. Owing to this circulation of the gas, a heat accumulated in the reaction tube 104 can be promptly removed by a heat of evaporation of the mist. Thus, the temperature in the reaction tube 104 can be rapidly lowered, and the wafer boat 110 holding the processed wafers W can be unloaded from the reaction tube 104. As a result, a process throughput can be improved.

Experiments which were carried out for confirming effects of the substrate processing apparatus according to the present invention are described hereinbelow.

[Experiment 1]

An experiment was carried out on a cooling effect of the upper part of the processing vessel 2, which is an object to be cooled, in the plasma processing apparatus shown in FIG. 1. To be specific, the heaters 38 and 48 were turned on to heat the processing vessel 2 such that a temperature detected by the temperature sensor 49 was raised to 120° C. Then, an air containing a mist (Example 1) was circulated in the mist passage 5, while varying its flow rate. As a comparative example, an air (Comparative Example 1) was solely circulated in the mist passage 5, while varying its flow rate. Then, temperatures at which the detected temperature of the temperature sensor 49 became steady state were measured.

Similarly, the air containing the mist (Example 2) and the air solely (Comparative Example 2) were circulated in the mist passage 5 in the processing vessel 2 heated at 180° C., and temperatures at which the detected temperature of the temperature sensor 49 became steady state were measured.

FIG. 8 shows the results. As apparent from FIG. 8, irrespective of flow rates, the air containing the mist (Examples 1 and 2) is superior in a cooling effect to the air solely used. (Comparative Examples 1 and 2).

[Experiment 2]

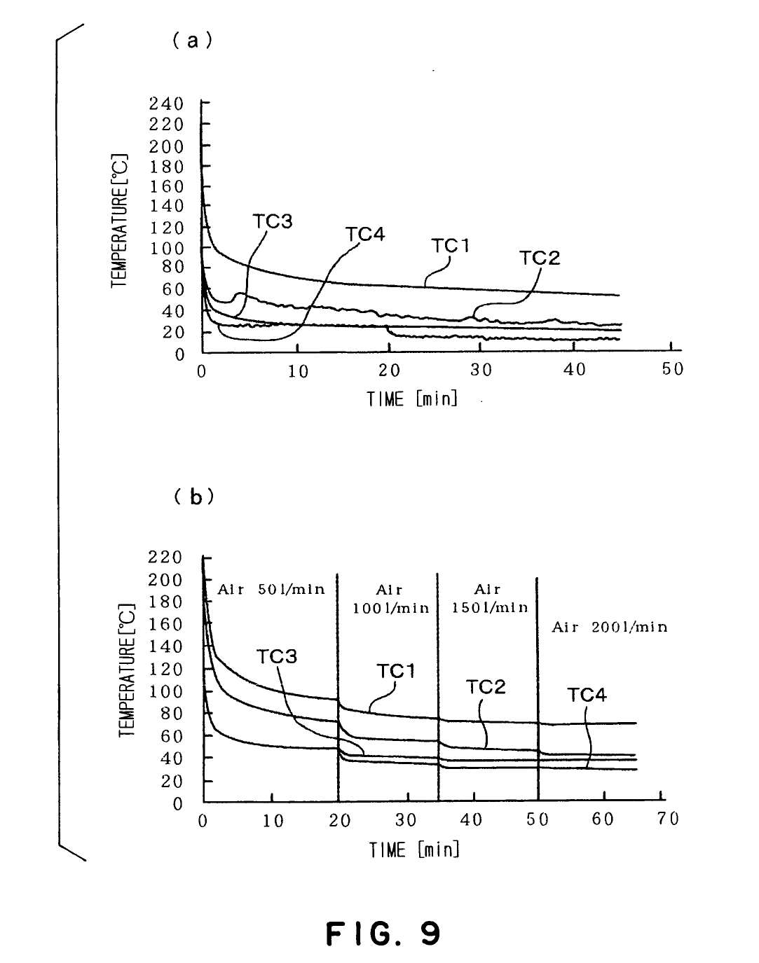

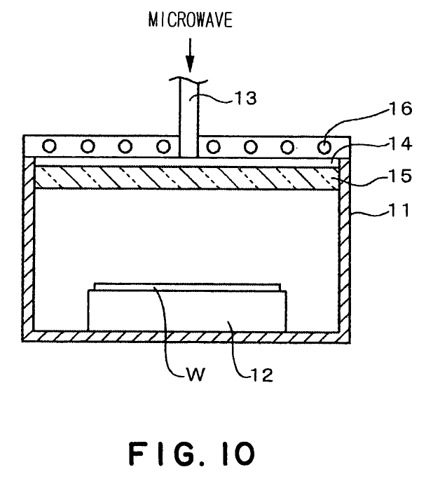

Another experiment was carried out to measure temperature changes at four points located in the antenna body 42 disposed on the upper part of the processing vessel 2, which is an object to be cooled, in the plasma processing apparatus shown in FIG. 1. To be specific, an air whose flow rate is 50 l/min and a mist (water) whose flow rate is 1 g/min were circulated in the mist passage 5, and temperature changes at the four points (TC1 to TC4) were observed. The results are shown in FIG. 9(a) as Example 3.

Similarly, an air without mist was circulated, and temperature changes at the four points (TC1 to TC4) were observed. The results are shown in FIG. 9(b) as Comparative Example 3. As shown in FIG. 9(b), the flow rate of air was increased as time elapsed.

As apparent from FIG. 9, at all the four points (TC1 to TC4), the air containing the mist (Example 3) is superior in a cooling effect to the air solely used (Comparative Example 3).

These experiment results demonstrate that, according to the present invention, the object to be cooled can be more rapidly cooled by a heat of evaporation of the mist, as compared with the conventional method.

1. A substrate processing apparatus for processing a substrate for manufacturing a semiconductor device, comprising an object to be cooled, the apparatus further comprising:
a mist generator that generates a mist;
a carrier-gas supply source that supplies a carrier gas for carrying the mist generated in the mist generator; and
a mist passage through which the mist carried by the carrier gas flows to cool the object.

2. The substrate processing apparatus according to claim 1, wherein
the object is at least a part of a processing vessel in which a substrate received therein is processed.

3. The substrate processing apparatus according to claim 2, wherein
the substrate is processed in the processing vessel with the use of a plasma.

4. The substrate processing apparatus according to claim 3, further comprising a heater that heats the object, at least when no plasma is generated.

5. The substrate processing apparatus according to claim 2, further comprising a heating furnace that receives the processing vessel, wherein
the mist passage is formed as a space defined between the processing vessel and the furnace.

6. The substrate processing apparatus according to claim 1, further comprising:
a temperature sensor that detects a temperature of the object; and
a controller that controls the mist generator and the gas supply source, based on a temperature detected by the temperature sensor.

7. The substrate processing apparatus according claim 6, wherein
the controller carries out a control operation to stop a generation of the mist by the mist generator and a supply of the carrier gas from the gas supply source, when the detected temperature of the temperature sensor is not more than a reference value.

8. The substrate processing apparatus according to claim 6, wherein
the controller carries out a control operation to stop a generation of the mist by the mist generator, while continuing a supply of the carrier gas from the gas supply source, when the detected temperature of the temperature sensor is not more than a reference value.

9. The substrate processing apparatus according to claim 6, wherein
the controller controls at least one of a flow rate of the mist and a flow rate of the carrier gas in the mist passage.

10. The substrate processing apparatus according to claim 1, further comprising a gas-liquid separator that separates the mist circulated in the mist passage from the carrier gas, and collects the separated mist as a liquid, wherein
the mist generator generates the mist from the liquid collected by the separator.
